(19) United States
(12) Patent Application Publication
(10) Pub. No.: US 2012/0202142 A1
(43) Pub. Date: Aug. 9, 2012

(54) MANUFACTURING METHOD OF EXPOSURE MASK, SHIPMENT JUDGMENT METHOD AND MANUFACTURING METHOD OF SEMICONDUCTOR DEVICE USING EXPOSURE MASK

(75) Inventors: Hiroyuki NISHIO, Oita-ken (JP); Satoshi USUI, Oita-ken (JP)

(73) Assignee: Kabushiki Kaisha Toshiba, Tokyo (JP)

(21) Appl. No.: 13/364,752

(22) Filed: Feb. 2, 2012

(30) Foreign Application Priority Data
Feb. 7, 2011 (JP) 2011-023999

(51) Int. Cl. G03F 7/20; G03F 1/70

(52) U.S. Cl. 430/5; 430/319

(57) ABSTRACT

A manufacturing method of a semiconductor device that produces a first mask having a first pattern including a alignment shift measuring pattern after exposure and a pattern inside a body integrated circuit, measures a position shift of the alignment shift measuring pattern after exposure and the position shift of the pattern inside the body integrated circuit to calculate a first difference, which is a difference of these position shifts, and reflects the first difference in a alignment parameter used when exposing treatment is provided to a wafer by using the first mask, and a shipment judgment method and a production method of an exposure mask.

### CROSS REFERENCE TO RELATED APPLICATIONS

This application is based upon and claims the benefit of priority from the prior Japanese Patent Application No. 2011-023999 filed in Japan on Feb. 7, 2011; the entire contents of which are incorporated herein by reference.

### FIELD

Embodiments described herein relate generally to a manufacturing method of a semiconductor device and a shipment judgment method and a production method of an exposure mask.

### BACKGROUND

As integrated circuit patterns in a semiconductor device become still finer in recent years, a problem of a substantial decrease in yield due to, for example, a short between a gate and substrate contact is posed. Such a decrease in yield results from alignment shifts of exposure masks and thus, improvement in alignment precision of exposure masks is required.

Usually, each exposure mask is formed by a drawing process and then differences of the mask pattern from the reference position is calculated for each mask to make a shipment judgment based on the calculated position shift amount.

Embodiments of the present invention are intended to provide a manufacturing method of a semiconductor device, a shipment judgment method and a production method of the exposure mask capable of reducing a misalignment between a pattern formed by an exposure mask and a pattern formed in a preceding process on which the pattern formed by the exposure mask is formed thereby preventing the decrease in yield.

### BRIEF DESCRIPTION OF THE DRAWINGS

FIG. 1 is a block diagram of a production system of an exposure mask and an exposing system using the exposure mask produced according to a first embodiment of the present invention;

FIG. 2 is a flow chart of production and exposure processes of the exposure mask according to the first embodiment;

FIG. 3 is a diagram showing position shift of a number of positions on the exposure mask A produced from respective reference positions on the exposure mask A according to the first embodiment;

FIG. 4 is a diagram showing position shift of a number of positions on the exposure mask B produced from respective reference positions on the exposure mask B according to the first embodiment;

FIG. 5 is a diagram showing an average position shift of the mask patterns calculated for the exposure masks A, B according to the first embodiment;

FIG. 6 is a block diagram of a production system of an exposure mask and an exposing system using the exposure mask produced according to a second embodiment of the present invention;

FIG. 7 is a flow chart of production and exposure processes of the exposure mask according to the second embodiment;

FIG. 8 is a diagram showing position shift of a number of positions on the exposure mask C produced from respective reference positions on the exposure mask C according to the second embodiment;

FIG. 9 is a diagram exemplifying a position shift of a pattern for measuring alignment shift after exposure and of a pattern inside an integrated circuit from respective reference positions according to the second embodiment;

FIG. 10 is a flow chart of production system of an exposure mask and an exposing system using the exposure mask produced according to a third embodiment of the present invention;

FIG. 11 is a diagram showing a position shift of a number of positions on the exposure mask D produced and respective reference positions on the exposure mask D according to the third embodiment;

FIG. 12 is a diagram exemplifying an average position shift of the patterns for measuring an alignment shift after exposure and of patterns inside an integrated circuit from respective reference positions of the exposure mask D and showing a difference between them.

FIG. 13 is a diagram showing a position shift of a number of positions on the exposure mask E produced from respective reference positions on the exposure mask E according to the third embodiment of the present invention;

FIG. 14 is a diagram exemplifying a position shift of patterns for measuring alignment shift after exposure and of patterns inside an integrated circuit from respective reference positions of the exposure mask E and showing a difference between them.

FIG. 15 is a diagram exemplifying the difference vectors shown in FIG. 12 and FIG. 14 respectively and a difference vector F between them.

### DETAILED DESCRIPTION

According to an embodiment of the present invention, a manufacturing method of a semiconductor device is provided. According to the manufacturing method of a semiconductor device, a first mask having a first pattern including an alignment shift measuring pattern after exposure and a pattern inside a body integrated circuit is produced, a position shift of the alignment shift measuring pattern after exposure and the position shift of the pattern inside the body integrated circuit in the first pattern are measured to calculate a first difference, which is a difference of these position shifts, and the first difference is reflected in a alignment parameter used in an exposing process of a wafer using the first mask.

According to an embodiment of the present invention, a shipment judgment method of an exposure mask is provided. According to the shipment judgment method of an exposure mask, a first mask for forming a first pattern is produced and a second mask for forming a second pattern is produced in alignment with the first pattern. A position shift amount of the mask pattern of the second mask with reference to the mask pattern of the first mask is calculated, and a shipment judgment is made based on the position shift amount.

According to an embodiment of the present invention, a production method of an exposure mask is provided. According to the production method of an exposure mask, a first mask to form a first pattern is produced, a pattern position shift of the first mask is measured, and drawing conditions for producing a second mask to form a second pattern formed in alignment with the first pattern are calculated based on the position shift.

The embodiments will be described below with reference to drawings.

### First Embodiment

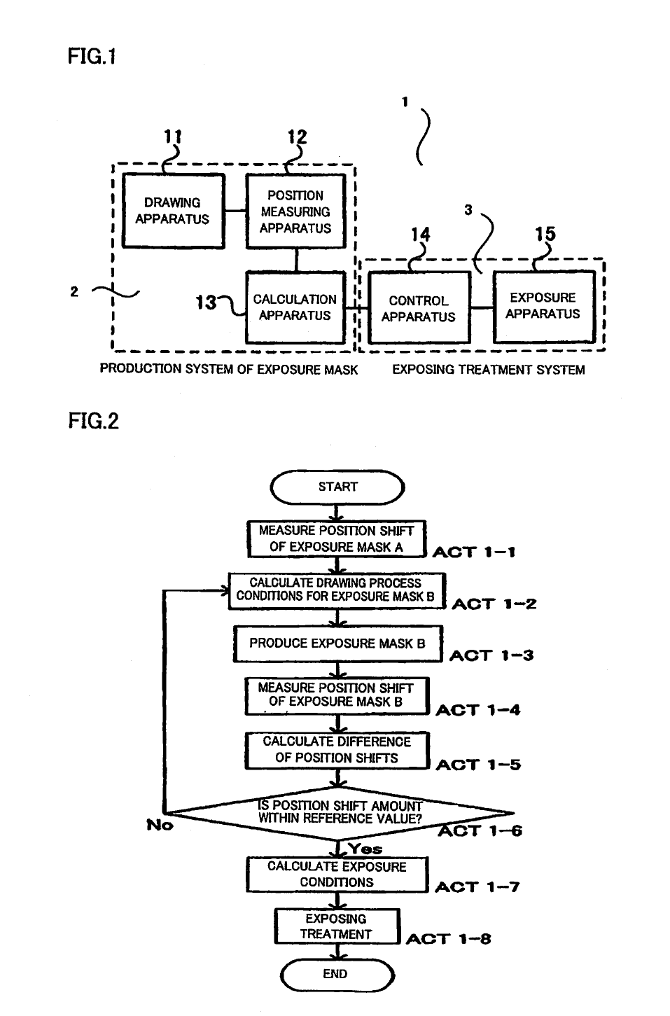

FIG. 1 shows a block diagram of a semiconductor manufacturing apparatus 1 according to the present embodiment. The manufacturing apparatus 1 of a semiconductor device includes a production apparatus 2 of an exposure mask and an exposing apparatus 3. The production apparatus 2 of an exposure mask includes a drawing apparatus 11 that produces an exposure mask, such as an electron beam machine, a position measuring apparatus 12 that measures a position shift between a number of positions on a mask pattern in a produced exposure mask and respective reference positions, and a calculation apparatus 13 that calculates a difference of measured position shifts and drawing process conditions. The exposing apparatus 3 includes a control apparatus 14 into which a difference of position shifts calculated by the calculation apparatus 13 is input and which calculates and controls exposure conditions based on the difference and an exposure apparatus 15 that provides exposing treatment to a wafer under the obtained exposure conditions by using the produced exposure mask.

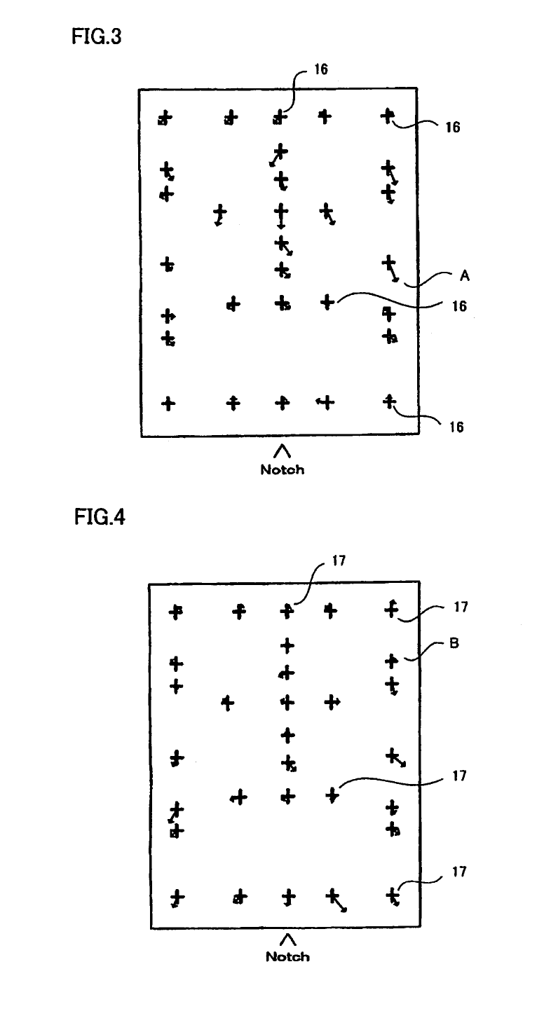

By using an exposure system as described above, an exposure mask is produced as described below and a wafer is exposed in a predetermined pattern. FIG. shows a flow chart of production and exposure processes of the exposure mask. First, the position measuring apparatus 12 measures position shifts between a number of positions on the mask pattern in an exposure mask A and their respective reference position as shown, for example, in FIG. 3 (Act 1-1). The exposure mask A is a mask used in an earlier process of a series of photolithography (PEP) process in manufacturing of a semiconductor device and is produced by the drawing apparatus 11. The mask will be called the exposure mask A below.

The exposure mask A shown in FIG. 3 is a photo mask to project a circuit pattern exposed in one shot by the exposing apparatus 3 onto a wafer. Detailed circuit patterns are omitted in FIG. 3, but a plurality of patterns (+ mark) 16 for measuring position shifts of the mask is shown and also position shift amounts and shift directions of the mask in these patterns 16 are indicated by arrows. That is, the position shift amount is indicated by the length of an arrow and the shift direction is indicated by the orientation of an arrow. “Notch” in FIG. 3 is a mark to indicate the arrangement position of a whole mask.

The reference position is a position in which each pattern 16 for measuring position shifts should be existed when the exposure mask A is placed in the center of a mask inspection apparatus. This also applies to the description below.

Such position shifts arise from various causes such as a mechanical distortion due to external force acting on the exposure mask A, expansion/contraction of materials caused by changes of the ambient temperature, and shifts caused by a drawing apparatus that produces an exposure mask.

Next, based on the position shifts detected by the position measuring apparatus 12, the calculation apparatus 13 calculates drawing process conditions for an exposure mask B newly formed for a process subsequent to the earlier process (Act 1-2). The drawing process conditions for the exposure mask B are calculated in such a way that the position of a drawing pattern in the exposure mask B is aligned with the corresponding position in the exposure mask A by considering position shifts detected as a result of measurement of the fitted exposure mask A by the position measuring apparatus 12.

Next, the exposure mask B as shown, for example, in FIG. 4 is newly produced by the drawing apparatus 11 under the calculated drawing process conditions (Act 1-3). Then, the position shifts between a number of positions on the mask pattern in an exposure mask B and their respective reference position are similarly measured by the position measuring apparatus 12 (Act 1-4). A plurality of + marks in FIG. 4 is marks 17 for measuring position shifts of the mask and, like in FIG. 3, the position shift amount (magnitude) and shift direction in each mark position are indicated by an arrow. “Notch” in FIG. 4 is a mark to indicate the arrangement position of a whole mask. Such position shifts similarly arise from various causes such as a mechanical distortion due to external force acting on the exposure mask B, expansion/contraction of materials caused by changes of the ambient temperature, and causes resulting from a drawing apparatus.

FIG. 5 is a diagram exemplifying position shifts of the mask patterns calculated by using the marks 16, 17 for measuring position shifts in the exposure masks A and B. While the position shift (vector a) of the mask pattern of the exposure mask A is in the lower left direction, the position shift (vector b) of the mask pattern of the exposure mask B is in the upper right direction.

Usually, if the shift amount (|vector b|) from the position serving as a reference does not exceed a reference value for shipment judgment of a product, the product is judged to be non-defective and shipped in the manufacture of an exposure mask. However, a position shift (vector b-a) arises in a pattern actually formed on a wafer, which is a position shift of the mask pattern of the exposure mask B with reference to the mask pattern of the exposure mask A and this leads to a decrease in yield.

Thus, the calculation apparatus 13 calculates a position shift of a mask pattern of the exposure mask B with reference to a mask pattern of the exposure mask A, that is, a difference (vector b-a) between the position shift of a mask pattern of the exposure mask A and the position shift of a mask pattern of the exposure mask B (Act 1-5). Then, the calculation apparatus 13 compares the position shift amount with a reference value, and judges as permission for shipment (OK) of the exposure mask B if the position shift amount is within the reference value and refusal of shipment (NG) if the position shift amount exceeds the reference value (Act 1-6).

Then, the control apparatus 14 calculates exposure conditions for the exposure mask B judged to be shippable based on the obtained difference of position shifts (Act 1-7) and the exposure apparatus 15 provides exposing treatment to a wafer on which a pattern has been formed by the exposure mask A by using the exposure mask B to be aligned with the exposure mask A (Act 1-8).

If the exposure mask B is judged to be not shippable, the calculation apparatus 13 calculates drawing process conditions for the exposure mask B based on the obtained difference of position shifts to create the exposure mask B again after returning to the step of Act 1-2. More specifically, the calculation apparatus 13 calculates drawing process conditions for the exposure mask B so that the exposure mask B is shifted by the same position shift amount (vector a) based on the position shift (vector a) of a mask pattern of the exposure mask A to create the mask. However, if, as a result of measurement by the position measuring apparatus 12, the position shift (vector b) of a mask pattern arises also in the mask B created as described above, the exposure mask B is created again by applying the obtained difference (vector a-b) amount of position shifts to drawing process conditions.

As the position shift amount (vector a)of a mask pattern of the exposure mask A, the average value of position shifts of each pattern 16 for measuring position shifts of the exposure mask A can also be used. The (vector b) showing the position shift amount of a mask pattern of the exposure mask B similarly can be shown by the average value of position shifts of each pattern 17 for measuring position shifts of the exposure mask B. By using the average values of position shifts in each pattern 16, 17 for measuring position shifts as described above, the calculation of drawing conditions for drawing a mask pattern by a drawing apparatus or reflection of a differential vector in drawing processes is simplified so that work efficiency can be improved.

Thus, according to the present embodiment, the alignment shift from a pattern formed in the earlier process can be reduced by calculating drawing process conditions for a newly formed exposure mask based on the position shift of a mask pattern of the fitted exposure mask. Then, yield due to the alignment shift from a pattern formed in the earlier process can be improved by making a judgment based on the position shift amount with reference to a mask pattern with which the newly formed exposure mask is aligned in the shipment judgment of an exposure mask.

### Second Embodiment

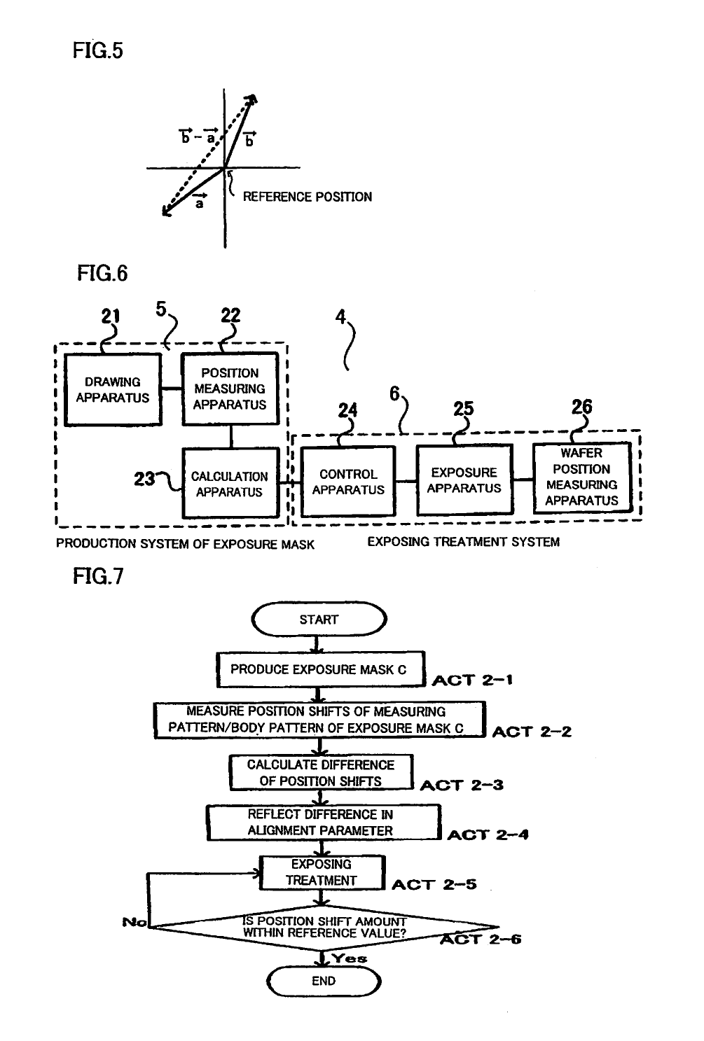

In the present embodiment, a semiconductor manufacturing apparatus 4 as shown in FIG. 6 is used. The semiconductor manufacturing apparatus 4 has the same configuration as in the first embodiment and includes a production apparatus 5 of an exposure mask and an exposing apparatus 6. The production apparatus 5 of an exposure mask includes a drawing apparatus 21 that produces an exposure mask, such as an electron beam machine, a position measuring apparatus 22 that measures a position shift of an alignment shift measuring pattern after exposure described later and of a pattern in a body integrated circuit formed in an exposure mask C produced by the drawing apparatus 21, and a calculation apparatus 23 that calculates a difference of measured position shifts. The exposing apparatus 6 includes an exposure apparatus 35 that reflects differences of the position shifts obtained by the calculation apparatus 23 to an alignment parameter and a wafer position measuring apparatus 26.

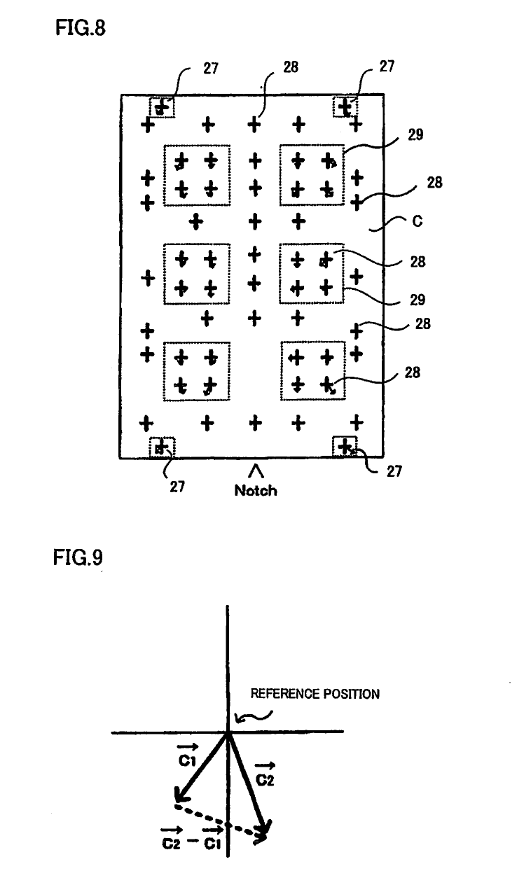

FIG. 7 shows a flow chart of production and exposure processes of the exposure mask C in the present embodiment. First, the exposure mask C is created by the drawing apparatus 21 (Act 2-1). That is, as shown, for example, in FIG. 8, two alignment shift measuring patterns after exposure (+) 27, each at upper and lower edges, and mask position shift amount measuring patterns (+) 28 arranged all over the mask are formed in the exposure mask C. In a region 29 enclosed by a dotted line quadrangle in FIG. 8, a circuit pattern forming an integrated circuit, though omitted, is formed and a plurality of the mask position shift amount measuring patterns 28 is formed in a free region inside the integrated circuit pattern. Next, the position measuring apparatus 22 measures position shifts of the alignment shift measuring patterns after exposure 27 and the mask position shift amount measuring patterns 28 inside the integrated circuit 29 from respective reference positions in the produced exposure mask C (Act 2-2).

FIG. 9 exemplifies the position shift of the alignment shift measuring pattern after exposure 27 and the position shift of the mask position shift amount measuring pattern 28 inside the integrated circuit 29. While the position shift (vector c₁) of the alignment shift measuring pattern after exposure is in the lower left direction, the position shift (vector c₂) of the pattern inside the integrated circuit is in the lower right direction, showing different directions.

If position shifts of the alignment shift measuring pattern after exposure 27 and the mask position shift amount measuring pattern 28 inside the integrated circuit are different as shown above, a result of measuring the alignment shift after exposure does not reflect the shift of pattern inside the integrated circuit by a manufacturing method of the exposure mask according to the prior art.

Thus, as shown together with FIG. 9, the calculation apparatus 23 calculates a difference (vector c₂-c₁) between the position shift of the alignment shift measuring pattern after exposure and the position shift of the mask position shift amount measuring pattern inside the integrated circuit (Act 2-3). Then, the control apparatus 24 reflects the obtained difference data in a alignment parameter (Act 2-4) and the exposure apparatus 25 provides exposing treatment to a wafer (Act 2-5). The reflection of the obtained difference data in a alignment parameter means correcting the alignment parameter based on the obtained difference data, but a correction cannot be made in each point of position shift measuring patterns in the exposing treatment of wafer and thus, a correction value obtained by averaging the position shift in all measuring points is reflected as a least shift. That is, the average value of position shifts of the four alignment shift measuring patterns after exposure 27 formed at two locations each at upper and lower edges is used as the position shift (vector c₁) of the alignment shift measuring pattern after exposure. Also as the position shift (vector c₂) of the mask position shift amount measuring pattern 28 inside the integrated circuit, the average value of position shifts of the mask position shift amount measuring pattern 28 contained in each of the regions 29. Then, the alignment parameter is corrected by using a difference of these average values (vector c₂-c₁) as a correction value.

Then, the wafer position measuring apparatus 26 measures the alignment shift of the wafer based on the alignment shift measuring pattern after exposure transferred onto the wafer. If the alignment shift is within a reference value, the exposure mask is judged to be shippable (OK) and distributed and if the alignment shift exceeds the reference value, the exposure mask is judged to be not shippable (NG) (Act 2-6) and exposing treatment is provided again.

If exposing treatment is provided again, the exposing treatment is provided by adjusting the shift amount in each of the X/Y directions for exposure and applying the shift amounts to an exposure apparatus so that the alignment shift amount of wafer measured based on the alignment shift measuring pattern after exposure 27 is within a reference value.

Thus, according to the present embodiment, the shift of a pattern inside the integrated circuit can be reflected in a result of measuring the alignment shift after exposure more precisely by providing exposing treatment to a wafer after reflecting a difference between the position shift of the alignment shift measuring pattern after exposure and the position shift of the pattern inside the integrated circuit in the alignment parameter so that the position shift of wafer can be judged with high precision. Then, a decrease in yield due to the alignment shift can be prevented.

### Third Embodiment

In the present embodiment, a system configuration similar to the system configuration in the second embodiment is used, but is different from the second embodiment in that, like in the first embodiment, the position shift is also measured using a mask pattern of the mask used in an earlier process of PEP to which a new exposure mask produced is aligned in a later PEP process.

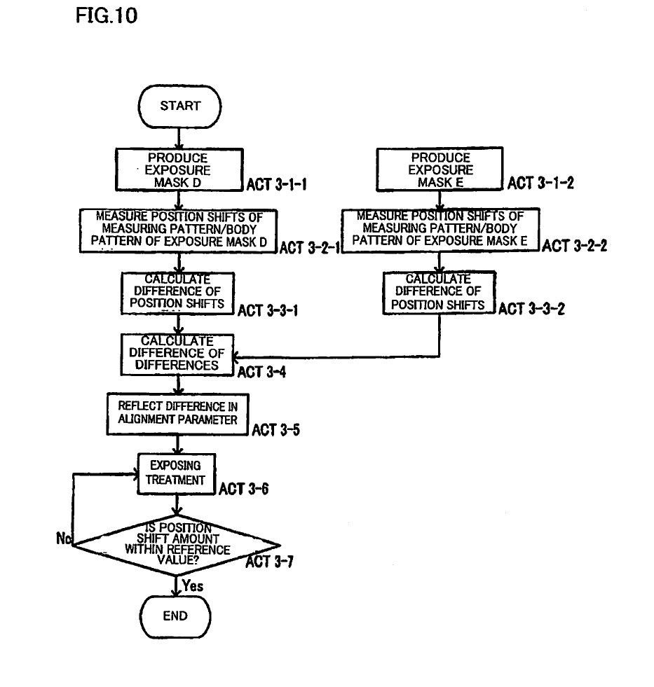

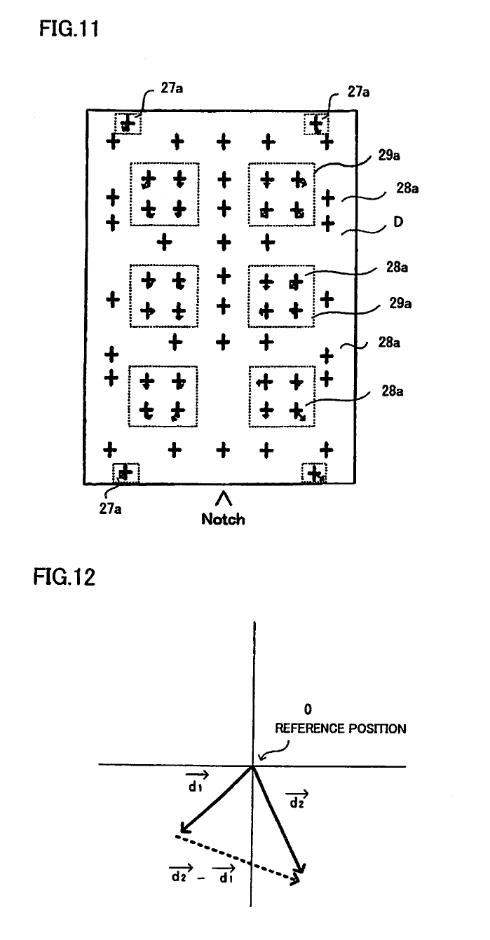

FIG. 10 shows a flow chart of production and exposure processes of the exposure mask according to the present embodiment. First, the drawing apparatus 21 shown in FIG. 6 produces the exposure mask D, which is used in an earlier process as shown, for example, in FIG. 11 by a drawing process (Act 3-1-1). The exposure mask D is substantially the same as the exposure mask C in the second embodiment shown in FIG. 8 and thus, the corresponding portion is indicated by the same number with a small letter a attached and a detailed description thereof is omitted. The exposure mask D includes an alignment shift measuring pattern after exposure 27a and a mask position shift measuring pattern 28a inside a body integrated circuit 29a. Next, the position measuring apparatus 22 shown in FIG. 6 measures position shifts of the alignment shift measuring pattern after exposure 27a and the mask position shift measuring pattern 28a inside the integrated circuit 29a of the obtained exposure mask D (Act 3-2-1). Then, like in the second embodiment, the calculation apparatus 23 calculates a difference between the average value of position shifts of the alignment shift measuring patterns after exposure 27a and the position shift of the mask position shift measuring pattern 28a inside the integrated circuit 29a (Act 3-3-1).

FIG. 12 exemplifies the average value (vector d₁) of position shifts of the alignment shift measuring patterns after exposure 27a, the position shift (vector d₂) of the mask position shift measuring pattern 28a inside the integrated circuit 29′, and a difference (vector d₂-d₁) between these vectors in the exposure mask D.

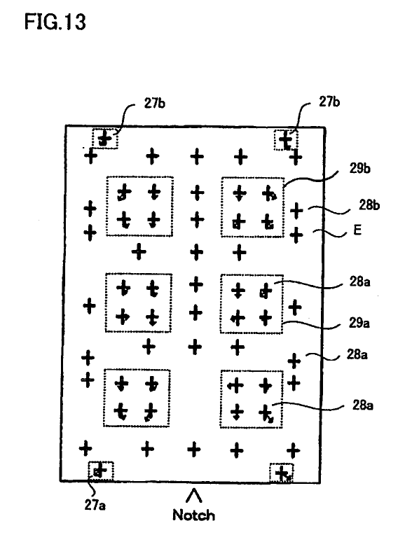

Similarly, the drawing apparatus 21 shown in FIG. 6 produces a new exposure mask E, which is aligned with the exposure mask D, by the drawing process (Act 3-1-2). Like the exposure mask D shown in FIG. 11, the exposure mask E includes, as shown, for example, in FIG. 13, an alignment shift measuring pattern after exposure 27b and a mask position shift measuring pattern 28b inside the integrated circuit 29b. The exposure mask E has substantially the same configuration as the exposure mask D shown in FIG. 11 except for a circuit configuration (not shown) inside the integrated circuit 29 and thus, the corresponding portion is indicated by the same number with a lower-case letter b attached. For the creation of the new exposure mask E, drawing process conditions for the exposure mask E may be calculated based on a difference of position shifts in the exposure mask D obtained previously. Next, the position measuring apparatus 22 shown in FIG. 6 measures position shifts of the alignment shift measuring pattern after exposure 27b and the mask position shift measuring pattern 28b inside the integrated circuit 29b of the obtained exposure mask E (Act 3-2-2). Then, like in the second embodiment, the calculation apparatus 23 shown in FIG. 6 calculates a difference between the average value of position shifts of the alignment shift measuring patterns after exposure 27b and the position shift of the mask position shift measuring pattern 28b inside the integrated circuit 29b (Act 3-3-2).

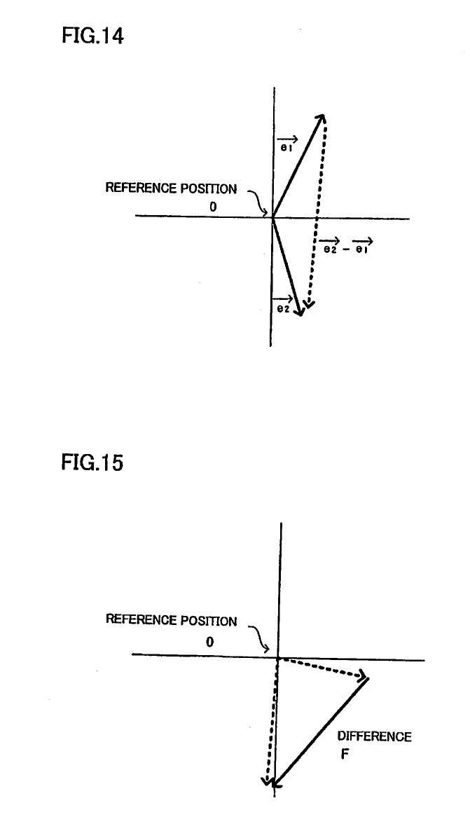

FIG. 14 exemplifies the position shift (vector e₁) of the alignment shift measuring patterns after exposure 27b, the position shift (vector e₂) of the mask position shift measuring pattern 28b inside the integrated circuit 29b, and a difference (vector e₂-e₁) between these vectors in the exposure mask E.

Then, the calculation apparatus 23 shown in FIG. calculates, as exemplified in FIG. 15, a differential vector F between the differential vector d₂-d₁ shown in FIG. 12 and the differential vector e₂-e₁ shown in FIG. 14 (Act 3-4).

Then, the control apparatus 24 shown in FIG. 6 reflects the obtained difference data in the alignment parameter (Act 3-5) and the exposure apparatus 25 exposes a wafer on which a pattern has been formed by the exposure mask D in the preceding process by using the exposure mask E (Act 3-6). In the reflection of the obtained difference data in the alignment parameter, as described in the second embodiment, the average value of differences between the average value (vector d₁) of position shifts of the alignment shift measuring patterns after exposure 27a and the position shift (vector d₂) of a pattern inside the integrated circuit 29 in the exposure mask D is used as the differential vector d₂-d₁. Also, the average value of differences between the average value (vector e₁) of position shifts of the alignment shift measuring patterns after exposure 27b and the position shift (vector e₂) of the mask position shift measuring pattern 28b inside the integrated circuit 29b in the exposure mask E is used as the differential vector e₂-e₁. Then, the wafer position measuring apparatus 26 measures the alignment shift of the wafer based on the alignment shift measuring pattern after exposure. If the alignment shift is within a reference value, the exposure mask is judged to be shippable (OK) and distributed and if the alignment shift exceeds the reference value, the exposure mask is judged to be not shippable (NG) (Act 3-7) and exposing treatment is provided again. If exposing treatment is provided again, the exposing treatment is provided by applying the shift amount in each of the X/Y directions for exposure to an exposure apparatus so that the alignment shift amount of wafer measured based on the alignment shift measuring pattern after exposure is within a reference value.

Thus, according to the present embodiment, the alignment shift from a pattern formed in the earlier process can be reduced by calculating drawing process conditions for a newly formed exposure mask based on the position shift of a mask pattern of the exposure mask used in the earlier process to which the newly formed exposure mask is aligned. Also, the shift of a pattern inside the integrated circuit can be reflected in a result of measuring the alignment shift after exposure more precisely by providing exposing treatment to a wafer after reflecting a difference between the position shift of the alignment shift measuring pattern after exposure and the position shift of the pattern inside the integrated circuit in the alignment parameter so that the position shift of wafer can be judged with high precision. Then, a decrease in yield due to the alignment shift can be prevented.

According to the shipment judgment method and the production method of an exposure mask and the manufacturing method of a semiconductor device in the embodiments described above, the alignment shift between a pattern formed by using the exposure mask and a pattern formed by the earlier process to which the exposure mask is aligned can be reduced so that a decrease in yield can be prevented.

Some embodiments of the present invention have been described, but these embodiments are presented as examples and are not intended to limit the scope of the invention.

These embodiments can be embodied in various other forms and various omissions, substitutions, or alterations can be made without deviating from the spirit of the invention.

These embodiments and modifications thereof are included in the scope and spirit of the invention and likewise included in the invention as claimed in the claims and equivalents thereof.

What is claimed is:

1. A production method of an exposure mask, comprising:
manufacturing a first exposure mask on which a plurality of patterns for measuring a position shift is formed together with a first semiconductor circuit pattern to form the first circuit pattern on a semiconductor wafer by using a drawing apparatus;
measuring the position shifts from reference positions of the plurality of patterns for measuring the position shift formed on the first exposure mask manufactured by using the drawing apparatus by using a position measuring apparatus;
calculating drawing conditions for manufacturing a second exposure mask for forming a second circuit pattern on the semiconductor wafer by alignment to the first circuit pattern based on the position shifts from the reference positions of the plurality of patterns for measuring the position shift measured by the position measuring apparatus by a calculator; and
manufacturing a second exposure mask for forming the second circuit pattern formed on the semiconductor wafer by alignment to the first pattern by using the drawing apparatus using the calculated drawing conditions.

2. The production method of an exposure mask according to claim 1, wherein the plurality of patterns for measuring the position shift is distributed and arranged over an entire region of the first exposure mask.

3. The production method of an exposure mask according to claim 2, wherein the position shifts from the reference positions of the plurality of patterns for measuring the position shift are each represented by vectors having a magnitude and a direction.

4. A shipment judgment method of an exposure mask, comprising the steps of:
manufacturing a first exposure mask for forming a first circuit pattern on a semiconductor wafer by using a drawing apparatus;
manufacturing a second exposure mask for forming a second circuit pattern formed on the semiconductor wafer by alignment to the first circuit pattern by using the drawing apparatus;
calculating a position shift amount of a mask pattern of the second exposure mask with reference to a mask pattern of the first exposure mask; and
making a shipment judgment of the second exposure mask based on the position shift amount.

5. The shipment judgment method of an exposure mask according to claim 4, wherein a plurality of patterns for measuring a position shift is formed on the first exposure mask together with the first semiconductor circuit pattern, the plurality of patterns for measuring the position shift is formed on the second exposure mask together with the second semiconductor circuit pattern, and the position shift amount of the mask pattern of the second exposure mask with reference to the mask pattern of the first exposure mask is calculated from differences between the shift amounts from reference positions of the plurality of patterns for measuring the position shift on the first exposure mask and reference positions of the plurality of patterns for measuring the position shift on the second exposure mask.

6. The shipment judgment method of an exposure mask according to claim 5, wherein the position shift amount of the mask pattern of the second exposure mask with reference to the mask pattern of the first exposure mask is calculated from the difference between an average value of the shift amounts from the reference positions of the plurality of patterns for measuring the position shift on the first exposure mask and the average value of the shift amounts from the reference positions of the plurality of patterns for measuring the position shift on the second exposure mask.

7. The shipment judgment method of an exposure mask according to claim 6, wherein the position shifts from the reference positions of the plurality of patterns for measuring the position shift are each represented by vectors having a magnitude and a direction.

8. A manufacturing method of a semiconductor device, comprising the steps of:
manufacturing a first exposure mask on which a first exposure pattern including a alignment shift measuring pattern after exposure and a mask position shift measuring pattern inside a body integrated circuit pattern by a drawing apparatus;
measuring each of a position shift of the alignment shift measuring pattern after exposure formed in the first exposure pattern and the position shift of the mask position shift measuring pattern inside the body integrated circuit by a position measuring apparatus; and
calculating a first difference, which is a difference between these position shifts, to reflect the first difference in a alignment parameter used to provide exposing treatment to a wafer by using the first mask.

9. The manufacturing method of a semiconductor device according to claim 6, wherein a plurality of the alignment shift measuring patterns after exposure is formed in a peripheral portion of the exposure mask and a plurality of the mask position shift measuring patterns is formed inside the integrated circuit pattern.

10. The manufacturing method of a semiconductor device according to claim 7, wherein the position shift of the alignment shift measuring pattern after exposure formed in the first exposure pattern is an average value of the position shifts of the plurality of alignment shift measuring patterns after exposure, the position shift of the mask position shift measuring pattern inside the integrated circuit is the average value of the position shifts of the plurality of mask position shift measuring patterns, and the first difference is the difference of these average values.

11. The manufacturing method of a semiconductor device according to claim 9, wherein the alignment shift measuring pattern after exposure and the mask position shift measuring pattern inside the integrated circuit pattern are each represented by vectors having a magnitude and a direction.

12. The manufacturing method of a semiconductor device according to any of claims 6 to 8, further comprising the steps of:
manufacturing a second mask for forming a second exposure pattern including the alignment shift measuring pattern after exposure and the mask position shift measuring pattern inside the integrated circuit pattern formed by alignment to the first exposure pattern;
measuring each of the position shift of the alignment shift measuring pattern after exposure in the second exposure pattern and the position shift of the mask position shift measuring pattern inside the integrated circuit pattern by the wafer position measuring apparatus;
calculating a second difference, which is the difference between these position shifts, to calculate a third difference, which is the difference between the second difference and the first difference, by a calculator; and
reflecting the third difference in a alignment parameter used to provide exposing treatment to a wafer by an exposure apparatus using the second exposure mask.

13. The manufacturing method of a semiconductor device according to claim 11, wherein the position shift of the alignment shift measuring pattern after exposure and the position shift of the mask position shift measuring pattern inside the integrated circuit pattern are each represented by the vectors having the magnitude and the direction.
